(19) United States
(12) Patent Application Publication
(10) Pub. No.: US 2002/0053055 A1
(43) Pub. Date: May 2, 2002

(54) Semiconductor device having a test mode

(75) Inventor: Kozo Ishida, Hyogo (JP)

Correspondence Address: McDERMOTT, WILL & EMERY, 600 13th Street, N.W., Washington, DC, 20005-3096, US

(73) Assignee: Mitsubishi Denki Kabushiki Kaisha

(21) Appl. No.: 09/839,416

(22) Filed: Apr. 23, 2001

(30) Foreign Application Priority Data
Nov. 2, 2000 (JP) 2000-335394

(51) Int. Cl. G01R 31/28

(52) U.S. Cl. 714/724

(57) ABSTRACT

In a semiconductor integrated circuit device, a plurality of tristate buffers provided corresponding to a plurality of internal signals respectively and receiving at its input node the corresponding internal signal are arranged distributed along the direction of extension of a tristate bus, and any of the plurality of tristate buffers is selectively activated, so that a desired internal signal is externally taken. Therefore, lines for taking the internal signals are not concentrated, and therefore a small circuit area is sufficient.

### BACKGROUND OF THE INVENTION

1. Field of the Invention

The present invention relates to a semiconductor device and, more specifically, to a semiconductor device having a test mode.

2. Description of the Background Art

Conventionally, in a semiconductor integrated circuit device, whether the semiconductor integrated circuit device operates normally as designed or not is tested after manufacturing, by applying a signal to an external input pin and monitoring a signal value applied at an external output pin.

According to the test method, however, it has been impossible to directly monitor a signal inside the semiconductor integrated circuit device. Therefore, it has been impossible to confirm in detail the operation in the semiconductor integrated circuit device. Even when there is some trouble in the semiconductor integrated circuit device, it has been difficult to analyze which circuit block of the device is out of order. Though it is possible to monitor a number of internal signals by providing a number of external output pins for monitoring the signals inside the semiconductor integrated circuit device, such an approach increases the cost of the semiconductor integrated circuit device. Accordingly, a semiconductor integrated circuit device has been proposed that enables monitoring of a number of internal signals by one external output pin.

FIG. 8 is a circuit block diagram showing a main portion of such a semiconductor integrated circuit device. Referring to FIG. 8, the semiconductor integrated circuit device includes a plurality of circuit blocks (CB) 51 to 53, . . . and a plurality of flip-flops 54 to 56, . . . . Each of the circuit blocks 51 to 53, . . . performs a prescribed operation in response to a signal from a preceding circuit block, for example. Each of the flip-flops 54 to 56, . . . operates in synchronization with a clock signal CLK, and transmits a signal from a preceding circuit block, for example, to a succeeding circuit block.

The semiconductor integrated circuit device further includes an external input pin 61, an n bit (where n is an integer not smaller than 2) shift register 62, a selector 63, a buffer 64 and an external output pin 65. To the external input pin 61, a shift register setting pattern DI including n bits of serial data is input in synchronization with the clock signal CLK. Shift register 62 takes the shift register setting pattern DI in synchronization with the clock signal CLK, and converts the n-bit serial data to n-bit parallel data.

Selector 63 selects any of the 2ⁿ bit internal signals in accordance with the n-bit parallel data, and applies a signal value (logic level) of the selected internal signal to the external output pin 65 through buffer 64. Therefore, in the semiconductor integrated circuit device, it is possible to selectively monitor 2ⁿ bit internal signals by one external output pin 65.

In the semiconductor integrated circuit device, however, when the number of signals to be monitored 2ⁿ increases, the selector 63 is increased in size, and the input signal lines to selector 63 are concentrated, significantly increasing the circuit area.

Further, it has been impossible to apply a desired signal to a desired circuit block through the external input pin 61 to test that circuit block.

### SUMMARY OF THE INVENTION

Therefore, an object of the present invention is to provide a semiconductor device having a small circuit area.

Another object of the present invention is to provide a semiconductor device which allows testing by applying a desired data signal to the internal circuitry.

The semiconductor device in accordance with the present invention includes: an external input terminal for receiving as an input, an external test signal in a test mode; a selecting circuit for selecting any of a plurality of internal signals of the semiconductor device in accordance with the test signal input through the external input terminal; a plurality of gate circuits provided corresponding to the plurality of internal signals, each receiving the corresponding internal signal at its input node, and applying the corresponding internal signal to an output node in response to selection of the corresponding internal signal by the selecting circuit; a signal transmitting line connected to output nodes of the plurality of gate circuits; and an external output terminal for externally outputting the internal signal applied to the signal transmitting line. Therefore, even when the number of internal signals as the object of testing increases, concentration of lines for the internal signals can be avoided when the plurality of gate circuits are arranged distributed along the direction of extension of the signal transmitting line, and a large selector is unnecessary, whereby increase in the circuit area can be suppressed.

Preferably, each gate circuit includes a tristate buffer that sets the output node to the same logic level as the logic level of the corresponding internal signal when the corresponding internal signal is selected by the selecting circuit, and sets the output node to the high impedance state when the corresponding internal signal is not selected. This facilitates configuration of the gate circuit.

Preferably, the plurality of gate circuits are divided into a plurality of groups in advance. The selecting circuit includes a designating circuit for designating any of the plurality of groups in accordance with a group designating signal included in the test signal, and a shift register provided corresponding to each group, taking a plurality of data signals contained in the test signal in response to designation of the corresponding group by the designating circuit, and applying the taken plurality of data signals to control nodes of the plurality of gate circuits belonging to the corresponding group, respectively. Each gate circuit applies, when the data signal applied to the control node thereof is at an active level, the corresponding internal signal to the output node. By such configuration, the length of the shift register can be reduced, and the data signal can be written to the shift register quickly.

Preferably, the signal transmission line and the external output terminal are provided same in number as the groups of the gate circuits. The plurality of signal transmission lines are provided corresponding to the plurality of groups, respectively, and each signal transmission line is connected to an output node of each gate circuit belonging to the corresponding group. The plurality of external output terminals are provided corresponding to the plurality of signal transmission lines, respectively, and each external output terminal is provided for externally outputting the internal signal applied to that corresponding signal transmission line. The designating circuit designates one or two or more groups among the plurality of groups, in accordance with the group designating signal. In that case, it is possible to simultaneously take a plurality of internal signals, enabling reduction of the test time.

The semiconductor device in accordance with another aspect of the present invention includes: an external input terminal receiving as an input an external test signal in the test mode; a first selecting circuit selecting one or two or more first internal signals among a plurality of first internal signals respectively of the semiconductor device in accordance with the test signal input through the external input terminal; a signal generating circuit generating a plurality of first data signals corresponding to the plurality of first internal signals respectively in accordance with the test signals; a plurality of first gate circuits provided corresponding to the plurality of first internal signals respectively, each receiving the corresponding first internal signal at a first input node thereof, receiving the corresponding first data signal at the second input node thereof, applying the corresponding first data signal to an output node when the corresponding first internal signal is selected by the first selecting circuit and applying the corresponding first internal signal to an output node when the corresponding first internal signal is not selected; and an internal circuit performing a prescribed operation based on an output signal of the plurality of first gate circuits. Therefore, as the first internal signal is replaced by the first data signal, it becomes possible to test the internal circuit by applying the first data signal of a desired logic level to the internal circuit.

Preferably, the plurality of first gate circuits are divided into a plurality of first groups in advance. The first selecting circuit includes a first designating circuit designating one or more of the plurality of first groups in accordance with a first group designating signal included in the test signal, and a first shift register corresponding to each first group, taking a plurality of second data signals included in the test signal in response to designation of the corresponding first group by the first designating circuit, and applying the taken plurality of second data signals to control nodes of the plurality of first gate circuits belonging to the corresponding first group, respectively. The signal generating circuit includes a second shift register provided corresponding to each first group, taking a plurality of first data signals included in the test signal in response to designation of the corresponding first group by the first designating circuit, and applying the plurality of first data signals to the second input node of a plurality of first gate circuits belonging to the corresponding first group, respectively. Each of the first gate circuits applies the first data signal to the output node when the second data signal applied to the control node has a first logic level, and applies the corresponding internal signal to the output node when the second data signal has a second logic level. By this configuration, the length of the shift register can be reduced, and the data signal can be written to the shift register quickly.

Preferably, the semiconductor device further includes: a second selecting circuit for selecting any of a plurality of second internal signals generated by the internal circuitry in accordance with the test signal; a plurality of second gate circuits provided corresponding to the plurality of second internal signals, each receiving at its input node the corresponding second internal signal and applying the corresponding second internal signal to an output node in response to selection by the corresponding second internal signal by the second selecting circuit; a signal transmission line connected to the output nodes of the plurality of second gate circuits; and an external output terminal for externally outputting the second internal signal applied to the signal transmission line. In that case, even if the number of second internal signals as the object of testing increases, concentration of the lines for internal signals can be avoided when the plurality of second gate circuits are arranged distributed along the direction of extension of the signal transmission line, and a large selector is unnecessary. Therefore, increase in the circuit area can be suppressed.

Preferably, the second gate circuit includes a tristate buffer that sets, when the corresponding second internal signal is selected by the second selecting circuit, the output node to the same logic level as the logic level of the corresponding second internal signal, and sets the output node to the high impedance state when the corresponding second internal signal is not selected. In that case, the second gate circuit can be configured easily.

Preferably, the plurality of second gate circuits are divided into a plurality of second groups in advance. The second selecting circuit includes a second designating circuit designating any of the plurality of second groups in accordance with the second group designating signal included in the test signal, and a third shift register provided corresponding to each of the second groups, taking a plurality of third data signals included in the test signal in response to designation of the corresponding second group by the second designating circuit and applying the taken plurality of third data signals to control nodes of the plurality of second gate circuits belonging to the corresponding second group, respectively. Each third gate circuit applies, when the data signal applied to the control node is at the active level, the corresponding second internal signal to the output node. Here, the length of the shift register can be made short, and the data signal can be written to the shift register quickly.

Preferably, the signal transmission line and the external output terminal are provided in the same number as the number of groups of the second gate circuits. The plurality of signal transmission lines are provided corresponding to the plurality of second groups, respectively. Each signal transmission line is connected to the output node of each second group belonging to the plurality of second groups, and the plurality of external output terminals are provided corresponding to the plurality of signal transmission lines, respectively, each for externally outputting the second internal signal applied to the corresponding signal transmission line. The second designating circuit designates one or two or more second groups among the plurality of second groups in accordance with the second group designating signal. Here, it is possible to take a plurality of second internal signals simultaneously, enabling reduction of test time.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIGS. 1A and 1B are circuit block diagrams representing main portions of the semiconductor integrated circuit device in accordance with one embodiment of the present invention.

FIG. 2 is a circuit diagram representing a configuration of a group of signal value setting shift registers shown in FIG. 1.

FIG. 3 is a circuit diagram representing a configuration of a group of signal monitoring shift registers shown in FIG. 1.

FIGS. 4A to 4E are time charts representing the method of testing the semiconductor integrated circuit device shown in FIGS. 1 to 3.

FIGS. 5A to 5E are time charts representing a modification of an embodiment of the present invention.

FIG. 6 is a circuit diagram representing another modification of an embodiment of the present invention.

FIG. 7 is a circuit block diagram representing a further modification of an embodiment of the present invention.

FIG. 8 is a circuit block diagram representing a main portion of a conventional semiconductor integrated circuit device.

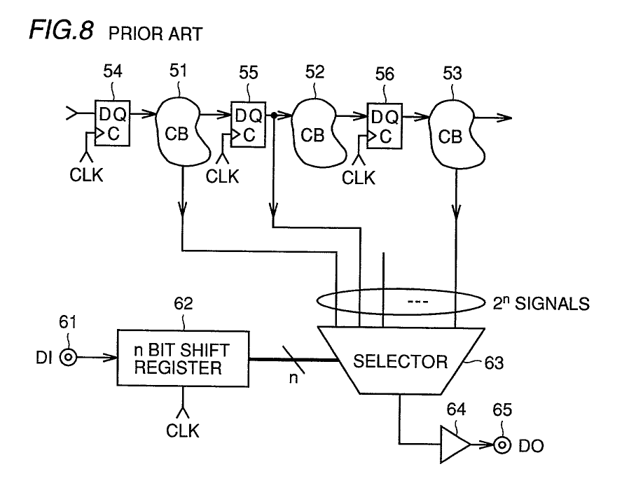

### DESCRIPTION OF THE PREFERRED EMBODIMENTS

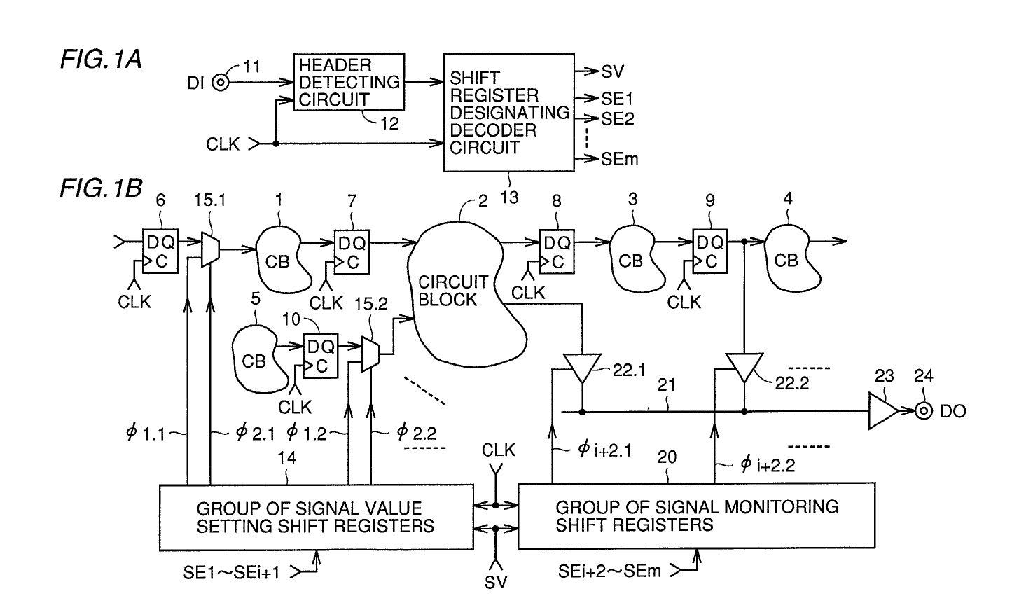

FIGS. 1A and 1B are circuit block diagrams representing main portions of the semiconductor integrated circuit device in accordance with one embodiment of the present invention.

Referring to FIGS. 1A and 1B, the semiconductor integrated circuit device includes a plurality of circuit blocks 1 to 5, . . . and a plurality of flip-flops 6 to 10, . . . . Each of the circuit blocks 1 to 5, . . . performs a prescribed operation in response to a signal from a preceding circuit block, for example. Each of the flip-flops 6 to 10, . . . operates in synchronization with the clock signal CLK, and transmits a signal from a preceding circuit block, for example, to a succeeding circuit block.

The semiconductor integrated circuit device includes an external input pin 11, a header detecting circuit 12 and a shift register designating decoder circuit 13. To the external input pin 11, a shift register setting pattern DI is input in synchronization with the clock signal CLK. Header detecting circuit 12 operates in synchronization with the clock signal CLK, and determines whether the head portion of the shift register setting pattern DI input through the external input pin 11 matches a predetermined header pattern or not. When it is determined to be matching, the detecting circuit transmits a shift register designating pattern and a shift register value setting pattern following the header pattern to shift register designating decoder circuit 13.

Shift register designating decoder circuit 13 operates in synchronization with the clock signal CLK, and sets any of the plurality of shift register activating signals SE1 to SEm (where m is a natural number) to an active level of “H” in accordance with the shift register designating pattern input through the header detecting circuit 12. Further, the shift register designating decoder circuit 13 applies a shift register value setting signal SV to that shift register which corresponds to the shift register activating signal set to the “H” level in accordance with the shift register value setting pattern, as will be described later.

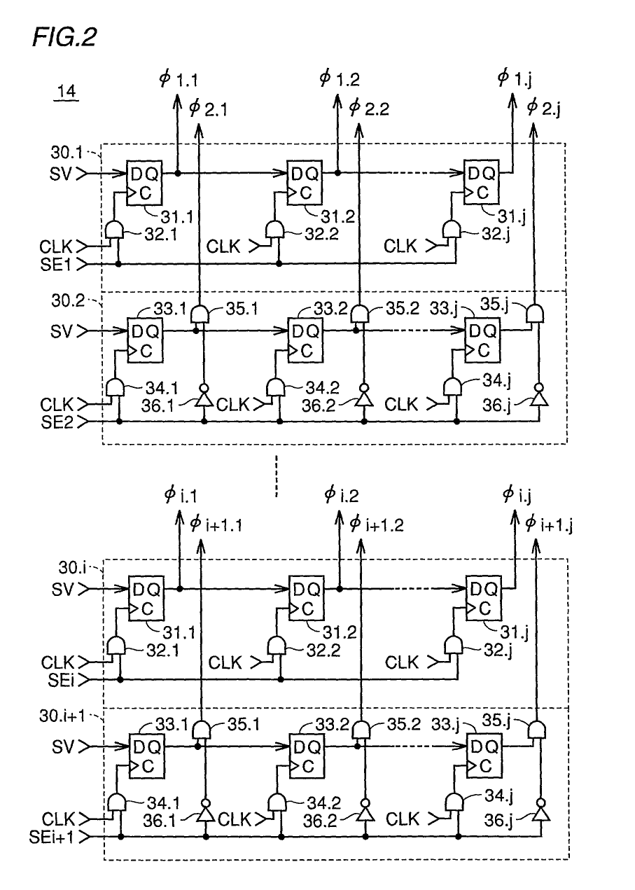

The semiconductor integrated circuit device further includes a group 14 of signal value setting shift registers and, a plurality of selectors 15.1, 15.2, . . . . The group 14 of signal value setting shift registers includes, as shown in FIG. 2, signal value storing shift registers 30.1, 30.3, . . . , 30.i (where i is an odd-number not smaller than 3 and smaller than m), and setting signal designating shift registers 30.2, 30.4, . . . , 30.i+1.

The signal value storing shift register 30.1 includes flip-flops 31.1-30.j and AND gates 32.1-32.j (where j is a natural number). To the flip-flop 31.1 of the first stage, a shift register value setting signal SV including j bit serial data is input. Output signals φ1.1-φ1.j−1 from flip-flops 31.1-31.j−1 are input to flip-flops 31.2 to 31.j of the succeeding stages, respectively. AND gates 32.1 to 32.j receive both the clock signal CLK and the shift register activating signal SE1, and respective output signals are input to a clock input terminal C of flip-flops 31.1 to 31.j. Output signals φ1.1 to φ1.j of flip-flops 31.1 to 31.j are input to one input node of selectors 15.1 to 15.j, respectively. Other signal value storing shift registers 30.3, . . . , 30.i also have the same configuration as the signal value storing shift register 30.1. Output signals φi.1 to φi.j of flip-flops 31.1 to 31.j of signal value storing shift register 30.1 are input to one input node of selectors 15.ji/2 to 15/j(i+1)/2, respectively.

For example, assume that only the signal SEi among the shift register activating signals SE1 to SEm is set to the active level of “H”. In that case, the clock signal CLK is input only to the clock input terminal C of flip-flops 31.1 to 31.j of shift register 30.1, and the clock input terminal C, and the clock input terminals C of other shift registers 30.2 to 30.i+1 are fixed at the “L” level. The j bit data included in the shift register value setting signal SV are successively taken by the flip-flops 31.1 to 31.j of shift register 30.1 in synchronization with the rising edge of clock signal CLK. The j bit data taken by the flip-flops 31.1 to 31.j will be the signals φ1.1 to φ1.j, respectively.

Setting signal designating shift register 30.2 includes flip-flops 33.1 to 33.j, AND gates 34.1 to 34.j, 35.1 to 35.j and inverters 36.1 to 36.j. To the flip-flop 33.1 of the first stage, the shift register value setting signal SV including j bit data is input. Output signals from flip-flops 33.1 to 33.j−1 are input to flip-flops 33.2 to 33.j of the succeeding stages, respectively. AND gates 34.1 to 34.j receive both the clock signal CLK and the shift register activating signal SE2, and respective output signals are input to the clock input terminal C of flip-flops 33.1 to 33.j.

Inverters 36.1 to 36.j invert the shift register activating signal SE2 and apply the resulting signal to one input node of AND gates 35.1 to 35.j, respectively. To the other input node of AND gates 35.1 to 35.j, output signals from flip-flops 33.1 to 33.j are input, respectively. Output signals φ2.1 to φ2.j of AND gate 35.1 to 35.j are input to control nodes of selectors 15.1 to 15.j, respectively. Other setting signal designating shift registers 30.4, . . . , 30.i+1 also have the same configuration as the setting signal designating shift register 30.2. Output signals φi+1.1 to φi+1.j of AND gates 35.1 to 35.j of setting signal designating shift registers 30.i+1 are input to control nodes of selectors 15.ji/2 to 15.j(i+1)/2, respectively.

Assume that only the signal SE2 among the shift register activating signals SE1 to SEm is set to the active level of “H”. Then, the clock signal CLK is input only to the clock input terminal C of flip-flops 33.1 to 33.j of shift register 30.2, and the clock input terminals C of flip-flops 33.1 to 33.j of other shift registers 30.1, 30.3 to 30.m are fixed at “L” level. The j bit data included in the shift register value setting signal SV are successively taken by the flip-flops 33.1 to 33.j of shift register 30.2 in synchronization with the rising edge of the clock signal CLK. The j bit data taken by flip-flops 33.1 to 33.j will be the signals φ2.1 to φ2.j in response to the fall of the signal SE2 from the “H” to “L” level.

Returning to FIGS. 1A and 1B, each of the selectors 15.1. 15.2, . . . is inserted between the output terminal Q of the flip-flop and the circuit block. Referring to FIG. 1, the other input node of selector 15.1 receives an output signal of flip-flop 6, and the output signal of selector 15.1 is input to the circuit block 1. Selector 15.1 applies the output signal of flip-flop 6 to circuit block 1 when the signal φ2.1 is at “L” level, and applies the signal φ1.1 to the circuit block 1 when the signal φ2.1 is at the “H” level. The other input node of selector 15.2 receives the output signal of flip-flop 10, and the output signal of selector 15.2 is input to the circuit block 2. Selector 15.2 applies the output signal of flip-flop 10 to the circuit block 2 when the signal φ2.2 is at the “L” level, and applies the signal 1.2 to the circuit block 2 when the signal 2.2 is at the “H” level. Operations of other selectors are the same as selectors 15.1 and 15.2.

The semiconductor integrated circuit device further includes a group 20 of signal monitoring shift registers, a tristate bus 21, tristate buffers 22.1, 22.2, . . . , a buffer 23 and an external output pin 24.

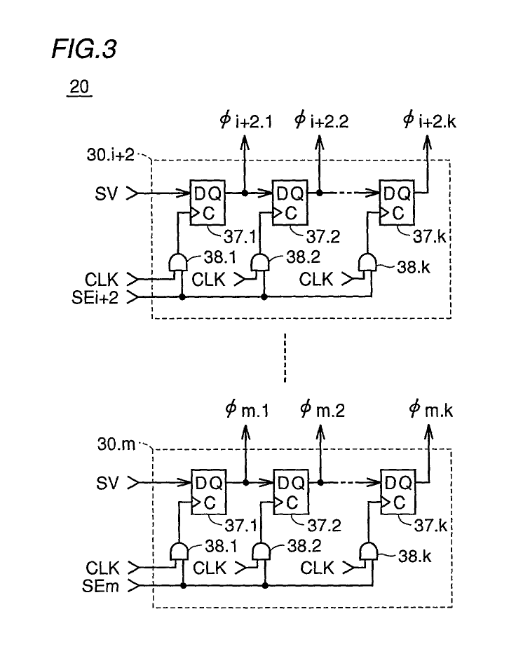

The group 20 for signal monitoring shift registers include, as shown in FIG. 3, a plurality of signal monitoring shift registers 30.i+2 to 30.m. Shift register 30.i+2 includes flip-flops 37.1 to 37.k (where k is a natural number) and AND gates 38.1 to 38.k. To the flip-flop 37.1 of the first stage, the shift register value setting signal SV including k bit data is input. Output signals i+2.1 to φi+2k−1 of flip-flops 37.1 to 37.k−1 are input to flip-flops 37.2 to 37.k of the succeeding stages, respectively. AND gates 38.1 to 38.k receive both the clock signal CLK and the shift register activating signal SEi+2, and respective output signals are input to the clock input terminals C of flip-flops 37.1 to 37.k. Output signals φi+1.2 to φi+2k of flip-flops 37.1 to 37.k are input to control nodes of tristate buffers 22.1 to 22.k, respectively. Other signal monitoring shift registers 30.i+3 to 30.m have the same configuration as the signal monitoring shift register 30.i+2. Output signals φm.1 to φm.k of flip-flops 37.1 to 37.k of signal monitoring shift registers 30.m are input to the control nodes of tristate buffers 22.k (m −i−2)+2 to 22.k(m−i−1), respectively.

Assume that only the signal SEi+2 among the shift register activating signals SE1 to SEm is set to the active level of “H”. The clock signal CLK is input only to the clock input terminals C of flip-flops 37.1 to 37.k of shift register 30.i+2, and the clock input terminals C of other shift registers 30.1 to 30.i+1, 30.i+3 to 30.m are fixed at the “L” level. The k bit data included in the shift register value setting signal SV are successively taken by the flip-flops 37.1 to 37.k of shift register 30.i+2, in synchronization with the rising edge of the clock signal CLK. The k bit data taken by flip-flops 37.1 to 37.k will be the signals φi+2.1 to φi+2.k.

Returning to FIGS. 1A and 1B, the tristate buffers 22.1 to 22.2, . . . are arranged along the direction of extension of the tristate bus 21. Tristate buffers 22.1 to 22.2, . . . have the input nodes receiving the internal signals of the semiconductor integrated circuit device, respectively, output nodes connected to tristate bus 21, and control nodes receiving signals φi+2.1 to φm.k, respectively. In FIGS. 1A and 1B, the input node of tristate buffer 22.1 receives an output signal from circuit block 2, and the input node of tristate buffer 22.2 receives an output signal of flip-flop 9.

When the signals φi+2.1 is at the “L” level, tristate buffers 22.1 is inactivated, and the output nodes of tristate buffer 22.1 is set to the high impedance state. When the signal φi+2.1 is at the “H” level, tristate buffer 22.1 is activated, and tristate buffer 22.1 transmits the level of the output signal of circuit block 2 to tristate bus 21. When the signal φi+2.2 is at the “H” level, tristate buffer 22.2 is activated, and tristate buffer 22.2 transmits the level of the output signal of flip-flop 9 to tristate bus 21. Operations of other tristate buffers 22.3 to 22.m are the same as the operations of tristate buffers 22.1 and 22.2. Buffer 23 transmits the level of tristate bus 21 to external output pin 24. At the external output pin 24, the level of the desired internal signal of the semiconductor integrated circuit device is output.

The method of testing the semiconductor integrated circuit device shown in FIGS. 1A to 3 will be described. When the semiconductor integrated circuit device is to be tested, first, a reset signal is applied to reset terminals (not shown) of all the flip-flops 31.1 to 31.j, 33.1 to 33.j and 37.1 to 37.k included in the group 14 of signal value setting shift registers and the group 20 of signal monitoring shift registers to reset these flip-flops, so that output signals from flip-flops 31.1 to 31.j, 33.1 to 33.j and 37.1 to 37.k are set to the “L” level.

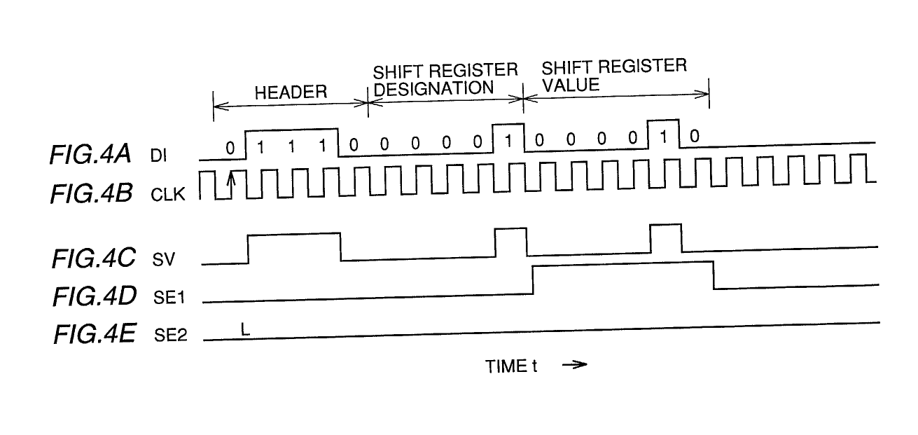

Thereafter, the shift register setting pattern DI is applied to external input pin 11, so that the shift register value setting signal SV for setting the signal value of an internal signal is stored in a desired signal value storing shift register. More specifically, the shift register setting pattern DI includes, as shown in FIGS. 4A to 4E, a header pattern having the plurality of data (5 bits in the shown example), a shift register designating pattern having the j bit (5 bits in the shown example) data and a shift register value pattern having the k bit data.

When the header pattern is a predetermined data pattern (01110 in the shown example), the shift register setting pattern DI is passed through the header detecting circuit 12 to shift register designating decoder circuit 13. The shift register value setting signal SV will be the same signal as the shift register setting pattern. Shift register designating decoder circuit 13 decodes the shift register designating pattern, selects any of the signals (SE1 in the shown example) among the plurality of shift register activating signals SE1 to SEm, and sets the selected signal SE1 to the active level of “H” only during the input period of the shift register value pattern. When the signal SE1 is set to the “H” level, the signal value storing shift register 30.1 corresponding to the signal SE1 is activated, and 6 bit data included in the shift register value setting signal SV are taken by the flip-flops 31.1 to 31.6 of shift register 30.1. Output signals φ5.1 to φ5.6 of flip-flops 31.1 to 31.6 are applied to one input node of the corresponding selectors 15.1, 15.2, . . . , respectively. Of the signals φ5.1 to φ5.6, only the signal φ5.1, for example, is set to the “H” level. When input of the shift register value pattern is terminated, the signal SE1 attains to the inactive level of “L”, and updating of the data held in flip-flops 31.1 to 31.6 of shift register 30.1 is stopped.

Thereafter, a new shift register setting pattern DI is applied to the external input pin 11, so that a shift register value setting signal SV for designating an internal signal of which signal value is set in a forced manner, is stored in a desired setting signal designating shift register. Storage of the shift register value setting signal SV in the setting signal designating shift register is performed in the similar manner as the storage of the shift register value setting signal SV in the signal value storing shift register. More specifically, shift register designating decoder circuit 13 decodes the shift register designating pattern input following the header pattern, selects any (for example, SE2) of the plurality of shift register activating signals SE1 to SEm, and sets the selected signal SE2 to the active level of “H” only during the input period of the shift register value pattern. When the signal SE2 is set to the “H” level, the setting signal designating shift register 30.2 corresponding to the signal SE2 is activated, and 6 bit data included in the shift register value setting signal SV are taken by the flip-flops 33.1 to 33.6 of shift register 30.2.

While the shift register value pattern is being input, the signal SE2 is at “H” level, and therefore, output signals φ2.1 to φ2.6 of AND gates 35.1 to 35.6 are fixed at the “L” level. When input of the shift register value pattern ends and the signal SE2 attains to the “L” level, output signals of flip-flops 33.1 to 33.6 pass through the AND gates 35.1 to 35.6 to be the signals φ2.1 to φ2.6. The signals φ2.1 to φ2.6 are applied to the control nodes of corresponding selectors 15.1, 15.2, . . . , respectively. Of the signals φ2.1 to φ2.6, only the signal φ2.2, for example, is set to “H” level and the signal φ1.2 is applied to circuit block 2 through selector 15.2. When the input of the shift register value pattern ends, the signal SE2 attains to the inactive level of “L”, and updating of the data held by flip-flops 31.1 to 31.6 of shift register 30.2 is stopped. In this manner, it is possible to set the input signal of a desired circuit block to a desired logic level.

Thereafter, a new shift register setting pattern DI is applied to the external input pin 11, and the shift register value setting signal SV for designating the internal signal to be monitored is stored in the signal monitoring shift register. Storage of the shift register value setting signal SV to the signal monitoring shift register is performed in the similar manner as the storage of the shift register value setting signal SV in the signal value storing shift register. More specifically, shift register designating decoder circuit 13 decodes the shift register designating pattern input following the header pattern, selects any of the signals (for example, SEi+2) of the plurality of shift register activating signals SE1 to SEm, and sets the selected signal SEi+2 to the active level of “H” only during the input period of the shift register value pattern. When the signal SEi+2 is set to the “H” level, the signal monitoring shift register 30.i+2 corresponding to the signal SEi+2 is activated, and 6 bit data included in the shift register value setting signal SV are taken by the flip-flops 37.1 to 37.6 of shift register 30.i+2.

The output signals φi+2.1 to φi+2.6 of flip-flops 37.1 to 37.6 are applied to the control nodes of corresponding tristate buffers 22.1 to 22.6, respectively. Of the signals φi+2.1 to φi+2.6, only the signal φi+2.2, for example, is set to the “H” level. When the signal φi+2.2 is set to the “H” level, tristate buffer 22.2 is activated, and the level of the output signal of flip-flop 9 is output through tristate buffer 22.2, tristate bus 21 and buffer 23 to the external output pin 24. When the input of the shift register value pattern ends, the signal SEi+2 attains to the inactive level of “L”, and updating of the data held by flip-flops 37.1 to 37.6 of shift register 30.i+2 is inhibited. By applying a new shift register setting pattern DI to the external input pin 11, it is possible to change the internal signal to be monitored.

In the present embodiment, as the plurality of tristate buffers 22.1, 22.2, . . . are arranged distributed along the direction of extension of tristate bus 21, and therefore lines for externally taking out the internal signals are not concentrated, and a large scale selector is unnecessary. Therefore, even when the number of internal signals as the object of testing increases, increase in the circuit area can be suppressed.

As the control signals φi+2.1 to φ.k of tristate buffers 22.1, 22.2, . . . are generated by the plurality of shift registers 30.i+2 to 30.m, it becomes possible to decrease the length of shift registers 30.i+2 to 30.m, and therefore the signal SV can be written to the shift registers 30.i+2 to 30.m in a short period of time.

Further, as the selectors 15.1, 15.2, . . . are provided for replacing the plurality of internal signals by the signals φ1.1 to φ1.j, . . . , respectively, it becomes possible to test circuit blocks 1, 2, . . . by applying a desired signal to circuit blocks 1, 2, . . . .

Further, as the signals φ1.1 to φ1.j, . . . are generated by the plurality of shift registers 30.1, 30.3, . . . , 30.i and control signals φ2.1 to φ2.j, . . . of selectors 15.1, 15.2, . . . are generated by the plurality of shift registers 30.2, 30.4, . . . , 30.i+1, the length of shift registers 30.1 to 30.i+1 can be made shorter, and therefore, the signal SV can be written to the shift registers 30.1 to 30.i+1 in a short period of time.

A modification of the present embodiment will be described in the following. In the semiconductor integrated circuit device shown in FIGS. 1 to 4E, only one of the shift register activating signals SE1 to SEm is set to the active level of “H”. However, two or more of the signals SE1 to SEm may be set to the active level of “H”.

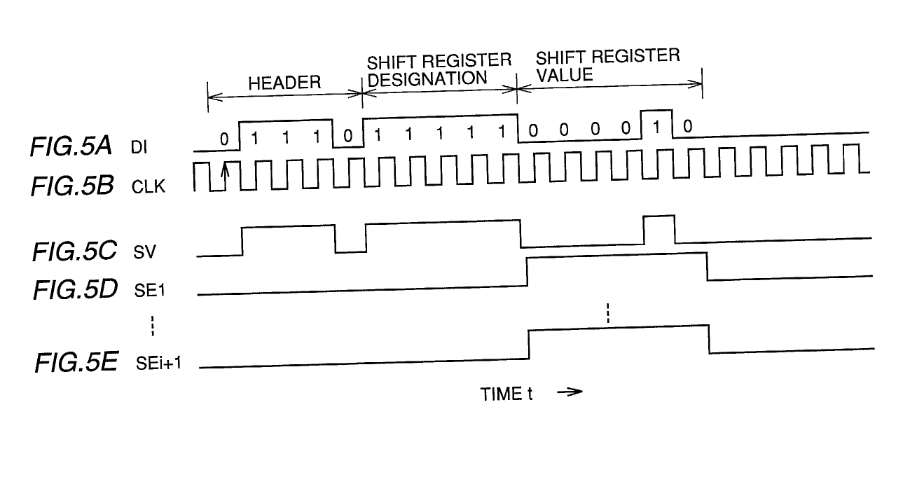

For example, when 5 bits of data included in the shift register designating pattern is 11111, as shown in FIGS. 5A to 5E, the signals SE1 to SEi+1 may be set to the active level of “H”, so that the same shift register value pattern (in the shown example, 000010) may be written to all the signal value storing shift registers 30.1, 30.3, . . . , 30.1 and setting signal designating shift registers 30.2, 30.4, . . . , 30.i+1.

When 5 bit data included in the shift register designating pattern are set to 11110, the signals SE1, SE3, . . . , SEi may be set to the active level of “H”, so that the same shift register value pattern may be written to all the signal value storing shift registers 30.1, 30.3, . . . , 30.i.

When 5 bit data included in the shift register designating pattern are set to 11101, the signals SE2, SE4, . . . , SEi+1 may be set to the active level of “H”, so that the same shift register value pattern may be written to all the setting signal designating shift registers 30.2, 30.4, . . . , 30.i+1. In this modification, the shift register value pattern can be written simultaneously to the plurality of shift registers, and therefore, writing of the shift register value pattern can be done quickly.

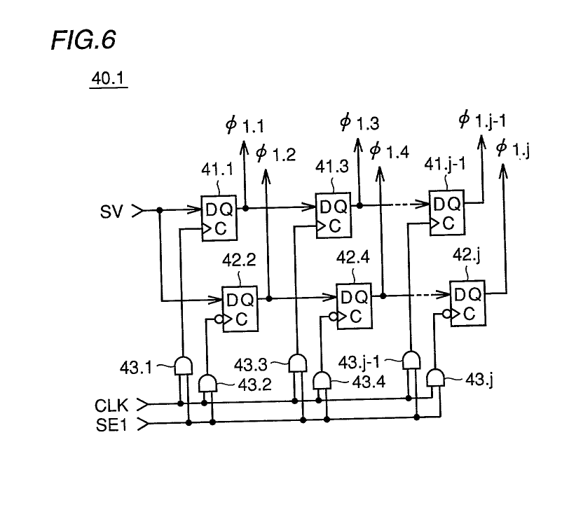

In the semiconductor integrated circuit device shown in FIGS. 1 to 4E, the shift register value setting signal SV is taken to the shift registers 30.1 to 30.m in synchronization with the rising edge only of the clock signal CLK. The shift register value setting signal SV, however, may be taken to the shift registers in synchronization with both the rising and falling edges of the clock signal CLK. More specifically, in the modification of FIG. 6, a signal value storing shift register 40.1 includes positive edge trigger type flip-flops 41.1, 41.3, . . . , 41.j−1 and negative edge trigger type flip-flops 42.2, 42.4, . . . , 42.j, and AND gates 43.1 to 43.j.

AND gates 43.1, 43.3, . . . 43.j−1 receive the clock signal CLK and the signal SE1, and respective output signals are input to the clock input terminals C of flip-flops 41.1, 41.3, . . . , 41.j−1. AND gates 43.2, 43.4, . . . , 43.j receive the clock signal CLK and the signal SE1, and respective output signals are input to the clock input terminals C of flip-flops 42.2, 42.4., . . . , 42.j. The signal SV is input to flip-flops 41.1, 42.2. Flip-flops 41.1, 41.3, . . . , 41.j−1 are connected in series, and respective output signals will be the signals φ1.1, φ1.3, . . . , φ1.j−1. Flip-flops 42.2, 42.4, . . . , 42.j are connected in series, and respective output signals will be the signals φ1.2, φ1.4, . . . , φ1.j.

When the signal SE1 attains to the active level of “H”, the clock signal CLK is input to the clock input terminal C of flip-flops 41.1, 41.3, . . . , 41.j−1 through AND gates 43.1, 43.3, . . . , 43.j−1, and input to the clock input terminals C of flip-flops 41.2, 41.4, . . . , 41.j through the AND gates 43.2, 43.4, . . . , 43.j. Each of the flip-flops 41.1, 41.3, . . . , 41.j−1 takes an input signal in response to the rising edge of the clock signal CLK. Each of the flip-flops 42.2, 42.3, . . . , 42.j takes the input signal in response to the falling edge of the clock signal CLK. Other signal value storing shift registers, the setting signal designating shift registers and the signal monitoring shift registers have the same configuration as shift register 40.1. Therefore, according to this modification, it is possible to take the shift register value setting signal SV to the shift registers at twice the speed of the semiconductor integrated circuit device shown in FIGS. 1 to 4E. It should be noted, however, that the frequency of the shift register setting pattern should be doubled.

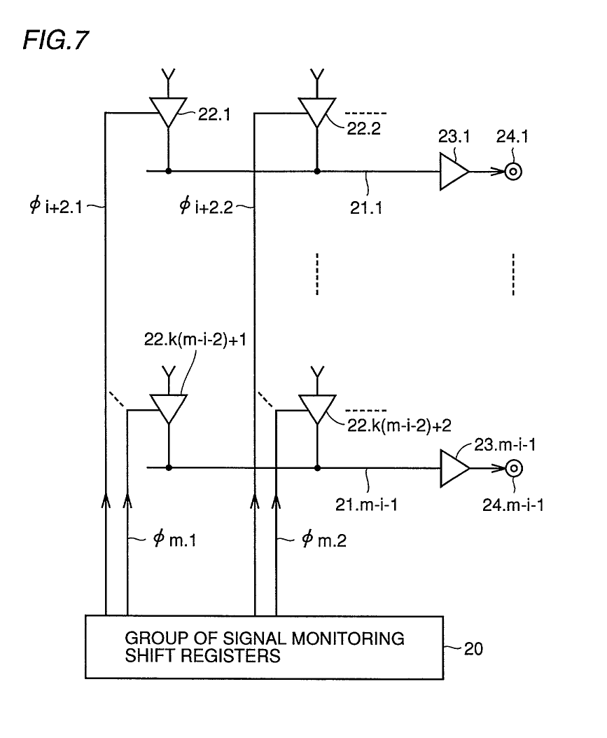

In the semiconductor integrated circuit device shown in FIGS. 1 to 4E, only one set of tristate bus 21, buffer 23 and external output pin 24 has been provided. There may be a plurality of sets. More specifically, in the modification shown in FIG. 7, tristate buses 21.1 to 21.m−i−1, buffers 23.1 to 23.m−i−1 and external output pins 24.1 to 24.m−i−1 are provided corresponding to the signal monitoring shift registers 30.i+2 to 30.m. Output nodes of tristate buffers 22.1 to 22.k corresponding to shift register 30.i+2 are connected to tristate bus 21.1. Output nodes of tristate buffers 22.k (m−i−2)+1 to 22.k (m−i−1) corresponding to shift register 30.m are connected to tristate bus 21.m−i−1. In this modification, since there are a plurality of external output pins 24.1 to 24.m−i−1, it becomes possible to simultaneously monitor a plurality of bits of internal signals by setting the signals SEi+2 to SEm simultaneously at the “H” level by the method described with reference to FIGS. 5A to 5E, and hence the semiconductor integrated circuit device can be tested in a short period of time.

Although the present invention has been described and illustrated in detail, it is clearly understood that the same is by way of illustration and example only and is not to be taken by way of limitation, the spirit and scope of the present invention being limited only by the terms of the appended claims.

What is claimed is:

1. A semiconductor device having a test mode, comprising:
an external input terminal for receiving as an input an external test signal in said test mode;
a selecting circuit selecting any of a plurality of internal signals of said semiconductor device in accordance with a test signal input through said external input terminals;
a plurality of gate circuits provided corresponding to said plurality of internal signals respectively, each receiving a corresponding internal signal at an input node, and applying the corresponding internal signal to an output node in response to selection of the corresponding internal signal by said selecting circuit;
a signal transmission line connected to the output nodes of said plurality of gate circuits; and
an external output terminal for externally outputting the internal signal applied to said signal transmission line.

2. The semiconductor device according to claim 1, wherein each gate circuit includes a tristate buffer setting said output node to a logic level same as the logic level of the corresponding internal signal when the corresponding internal signal is selected by said selecting circuit, and sets said output node to a high impedance state when the corresponding internal signal is not selected.

3. The semiconductor device according to claim 1, wherein
said plurality of gate circuits are divided into a plurality of groups in advance;
said selecting circuit includes
a designating circuit for designating any of said plurality of groups in accordance with a group designating signal included in said test signal, and
a shift register provided corresponding to each group, taking a plurality of data signals included in said test signal in response to designation of the corresponding group by said designating circuit, and applying the taken plurality of data signals to control nodes of a plurality of gate circuits belonging to the corresponding group, respectively and
each gate circuit applies the corresponding internal signal to said output node when the data signal applied to the control node has an active level, and does not apply the corresponding internal signal to said output node when said data signal has an inactive level.

4. The semiconductor device according to claim 3, wherein
said signal transmission line and said external output terminal are provided same in number as the number of groups of said gate circuits;
the plurality of said signal transmission lines are provided corresponding to said plurality of groups, respectively, each signal transmission line being connected to an output node of each of the gate circuits belonging to the corresponding group;
a plurality of said external output terminals are provided corresponding to said plurality of signal transmission lines, respectively, each external output terminal provided for externally outputting the internal signal applied to the corresponding signal transmission line; and
said designating circuit designates one or more groups among said plurality of groups in accordance with said group designating signal.

5. A semiconductor device having a test mode, comprising:
an external input terminal receiving as an input an external test signal in said test mode;
a first selecting circuit selecting one or more of a plurality of first internal signals of said semiconductor device in accordance with the test signal input through said external input terminal;
a signal generating circuit generating a plurality of first data signals corresponding to said plurality of first internal signals respectively in accordance with said test signal;
a plurality of first gate circuits provided corresponding to said plurality of first internal signals respectively, each receiving at a first input node, the corresponding first internal signal and at a second input node, the corresponding first data signal, applying the corresponding first data signal to an output node when the corresponding first internal signal is selected by said first selecting circuit, and applying the corresponding first internal signal to said output node when the corresponding first internal signal is not selected; and
an internal circuit performing a prescribed operation based on an output signal of said plurality of first gate circuits.

6. The semiconductor device according to claim 5, wherein
said plurality of first gate circuits are divided into a plurality of first groups in advance;
said first selecting circuit includes
a first designating circuit designating one or more of said plurality of first groups in accordance with a first group designating signal included in said test signal, and
a first shift register provided corresponding to each of the first groups, taking a plurality of second data signals included in said test signal in response to designation of the corresponding first group by said first designating circuit, and applying the taken plurality of second data signals to control nodes of a plurality of first gate circuits belonging to the corresponding first group, respectively;
said signal generating circuit includes a second shift register provided corresponding to each of the first groups, taking a plurality of the first data signals included in said test signal in response to designation of the corresponding first group by said first designating circuit, and applying the taken a plurality of first data signals to second input nodes of the plurality of first gate circuits belonging to the corresponding first group, respectively; and
each of the first gate circuits applies the corresponding first data signal to said output node when the second data signal applied to the control node has a first logic level, and applies the corresponding internal signal to said output node when said second data signal has a second logic level.

7. The semiconductor device according to claim 5, further comprising:
a second selecting circuit selecting any of a plurality of second internal signals generated by said internal circuit in accordance with said test signal;
a plurality of second gate circuits provided corresponding to said plurality of second internal signals respectively, each receiving at an input node the corresponding second internal signal and applying the corresponding second internal signal to an output node in response to selection of the corresponding second internal signal by said second selecting circuit;
a signal transmission line connected to the output nodes of said plurality of second gate circuits; and
an external output terminal for externally outputting the second internal signal applied to said signal transmission line.

8. The semiconductor device according to claim 7, wherein each of the second gate circuits includes a tristate buffer setting said output node to a logic level same as the logic level of the corresponding second internal signal when the corresponding second internal signal is selected by said second selecting circuit, and sets said output node to a high impedance state when the corresponding second internal signal is not selected.

9. The semiconductor device according to claim 7, wherein
said plurality of second gate circuits are divided into a plurality of second groups in advance;
said second selecting circuit includes
a second designating circuit designating any of said plurality of second groups in accordance with a second group designating signal included in said test signal, and
a third shift register provided corresponding to each of the second groups, taking a plurality of third data signals included in said test signal in response to designation of the corresponding second group by said second designating circuit, and applying the taken plurality of third data signals to control nodes of a plurality of second gate circuits belonging to the corresponding second group, respectively and
each of the third gate circuits applies the corresponding second internal signal to said output node when the third data signal applied to the control node has an active level, and does not apply the corresponding second internal signal to said output node when said third data signal has an inactive level.

10. The semiconductor device according to claim 9, wherein
said signal transmission line and said external output terminal are provided same in number as the number of groups of said second gate circuits;
the plurality of said signal transmission lines are provided corresponding to said plurality of second groups, respectively, each signal transmission line being connected to an output node of each of the second gate circuits belonging to the corresponding second group;
the plurality of said external output terminals are provided corresponding to said plurality of signal transmission lines, respectively, each external output terminal provided for externally outputting the second internal signal applied to the corresponding signal transmission line; and
said second designating circuit designates one or more of said plurality of second groups in accordance with said second group designating signal.
